(19) United States
(12) Patent Application Publication
(10) Pub. No.: US 2009/0109634 A1
(43) Pub. Date: Apr. 30, 2009

(54) PORTABLE ELECTRONIC DEVICE, AND SLIDING/ROTATION OPENING/CLOSING MODULE AND PARTS THEREOF FOR THE DEVICE

(75) Inventor: Han Sang LEE, Seoul (KR)

Correspondence Address: ROBERTS MLOTKOWSKI SAFRAN & COLE, P.C.;Intellectual Property Department, P.O. Box 10064, MCLEAN, VA, 22102-8064, US

(73) Assignees: Han Sang LEE, Seoul (KR); P & Tel Inc., Seoul (KR)

(21) Appl. No.: 12/255,431

(22) Filed: Oct. 21, 2008

(30) Foreign Application Priority Data
Oct. 26, 2007 (KR) 10-2007-0108507

(51) Int. Cl. H05K 7/16

(52) U.S. Cl. 361/727

(57) ABSTRACT

Disclosed is a portable electronic device, a sliding/rotation opening/closing module for the device, and parts thereof. The portable electronic device includes: a first body; a guide member, which is installed at the first body in such a manner that the guide member can rotate about a rotation axis member, and has a slide guide part; an interlocking member installed at between the first body and the guide member, the interlocking member interlocking relative movements of the first body and the guide member; a second body slidably installed at the slide guide part; a link device, which is installed between the guide member and the second lo body and has one side connected with the interlocking member, the link device being folded or unfolded while the link device is rotated by the interlocking member so as to allow the second body to slide when the guide member rotates, so that a relative position of the second body respective to the guide member changes.

### BACKGROUND OF THE INVENTION

1. Field of the invention

The present invention relates to a portable electronic device, an opening/closing module of the device, and a part thereof, and more particularly to a portable electronic device, a sliding/rotation opening/closing module of the device, and a part thereof.

2. Description of the Prior Art

In general, “portable electronic devices” are devices allowing a user to perform communication, play games, learn, listen to music, watch TV, etc. while carrying the devices.

As such a portable electronic device, there is a portable wireless phone, a PDA, an electronic calculator, an MP3 player, a notebook, a portable game player, etc. Such a portable electronic device may be referred to as a portable terminal.

In such a portable electronic device, functions are unified and diversified so that it is required to open one device in a sliding type opening/closing manner as well as a rotation type opening/closing manner. For example, in a case of a portable wireless phone having a DMB function, when the user wants to call his/her partner, the user opens a cover having a displayer installed thereon through sliding upward and downward so as to make a call. Meanwhile, when the user wants to watch TV, the user rotates the cover so as to allow a screen to be arranged in a transverse direction, and after watching TV, again rotates the cover so as to close it. Such a portable electronic device or module allowing a cover to be opened/closed through sliding and rotation is referred to as a sliding/rotation opening/closing portable electronic device or a sliding/rotation opening/closing module.

### SUMMARY OF THE INVENTION

The applicant has discovered that the conventional sliding/rotation opening/closing electronic device has problems as follows.

Among conventional sliding/rotation opening/closing electronic devices, there is an electronic device in which a user slides a cover toward an upper side of a main body so as to open the cover, and again rotates the cover so as to allow a displayer installed on the cover to be arranged in a transverse direction. However, in a state of the cover being rotated, the cover has to be positioned at a center based on left and right directions respective to the main body. Therefore, there is a disadvantage in that a sliding distance is short, and an area for installing keys, etc. on the main body cannot be sufficiently secured.

Also, in a case where the user wants to watch TV while carrying the sliding/rotation opening/closing electronic device, the user has to slide the cover in up direction and again rotate the cover so that there is inconvenience in using the device.

In addition, it can be considered that the user can rotate the cover in a state of the cover being closed without a need for sliding the cover. However, in order to adjust the center of the cover in left and right directions respective to the main body, a rotational center of the cover has to be deviated toward edges of the main body and the cover. In this state, if force is applied to a side opposite to the rotational center in a state of the cover being opened, there is concern in that a connection portion between the main body and the cover can be damaged.

The fact that the rotation center of the cover is deviated toward the edges of the main body and the cover becomes an obstacle in enlarging the width of the device.

Also, it is difficult to change the rotational center of the cover. Therefore, the device cannot be freely designed, and it is difficult to secure a large area of the main body, which is required for installing keys, etc., in a state of the cover being rotated.

In addition, a conventional terminal has a first body and a second body, which are assembled with each other at one position of a rotational shaft installed near an edge of the bodies. Therefore, the terminal isn't stable and is easily damaged.

Accordingly, the present invention has been made to solve the above-mentioned problems occurring in the prior art, and an object of the present invention is to provide a sliding/rotation opening/closing portable electronic device, in which a second body can restrictively slide while rotating on a first body when the second body is opened through rotation.

Also, another object of the present invention is to provide a sliding/rotation opening/closing portable electronic device, in which a center of a second body based on left and right directions respective to a first body can be adjusted regardless of a rotational center of the second body in a state of the second body being opened through rotation.

Also, another object of the present invention is to provide a sliding/rotation opening/closing portable electronic device, in which a rotational center of a second body can be moved from an edge of a first body toward an inner side of the first body.

Also, another object of the present invention is to provide a sliding/rotation opening/closing portable electronic device, which has a relatively large width thereof in comparison with a conventional portable electronic device.

Also, another object of the present invention is to provide a sliding/rotation opening/closing portable electronic device, in which a rotational center of a second body can be moved to a higher position in comparison with a conventional one.

Also, another object of the present invention is to provide a sliding/rotation opening/closing portable electronic device, in which first and second bodies are supported by at least two portions so that stability is secured, and there is less concern of the device being damaged.

Also, another object of the present invention is to provide a portable electronic device, in which an opened portion can be tilted.

Also, another object of the present invention is to provide a sliding/rotation opening/closing module, which can be suitably used in a portable electronic device according to the present invention.

Also, another object of the present invention is to provide a part, which can be suitably used in a portable electronic device or a module according to the present invention.

In accordance with an aspect of the present invention, there is provided a portable electronic device, which includes a first body; a guide member, which is installed at the first body in such a manner that the guide member can rotate about a rotation axis member, and has a slide guide part; an interlocking member installed at between the first body and the guide member, the interlocking member interlocking relative movements of the first body and the guide member through a section where a relative position of the interlocking member respective to the first body and the guide member changes according to each operation of the first body and the guide member when the guide member rotates; a second body slidably installed at the slide guide part; a link device, which is installed between the guide member and the second body and has one side connected with the interlocking member, the link device being folded or unfolded while the link device is rotated by the interlocking member so as to allow the second body to slide when the guide lo member rotates, so that a relative position of the second body respective to the guide member changes.

It is preferable that a slide limitation guide path is formed at the first body along a periphery of the rotation axis member and has a section where distance from the slide limitation guide path to a rotational center of the rotation axis member is changes, so that the slide limitation guide path restrictively allows the second body to slide along the guide member in such a manner that the slide limitation guide path allows the interlocking member to be restrictively moved while allowing the guide member to rotate when the guide member performs a rotational movement.

Also, it is preferable that an interlocking member guide path is formed at the guide member along a route having at least one portion intersected with the slide limitation guide path when the guide member rotates, and allows a position of the interlocking member respective to the first body and the guide member to be changed in a state where the interlocking member is interlocked.

It is preferable that the rotation axis member is installed at the first body in such a manner that it is deviated toward a right side or a left side of an upper end of the first body, and a degree of change in a distance between the slide limitation guide path and the rotational center of the rotation axis member in the section has been determined so as to allow the second body to slide along the slide guide part while rotating about the rotation axis member, thereby adjusting a transverse center of the second body with respect to the first body, when the second body is opened through rotation.

It is preferable that the first body has a rotation limiting part formed along a route, which prevents or restrictively allows rotation of the second body while allowing the second body to slide in performing a sliding operation.

It is preferable that the link device includes a first link member rotatably installed at the guide member, and a second link member, which is rotatably connected with the first link member and is rotatably supported by the second body, and the interlocking member is connected with one side of the first link member.

Also, it is preferable that the rotation limiting part is connected with one end of the slide limitation guide path, the rotation limiting part having a circular arc-shape having a center corresponding to a rotational center of the link device, and being formed in such a manner that the rotation limiting part overlaps the interlocking member guide path when the second body slides or is closed.

As the case may be, the link device preferably includes a first link member rotatably installed at the guide member, a second link member, which is rotatably connected with the first link member and is rotatably supported by the second body, and a third link member, which is rotatably installed at one side of the first link member and has one side connected with the interlocking member.

Also, it is preferable that the rotation limiting part is connected with one end of the slide limitation guide path, the rotation limiting part being shaped by a curved line or a linear line and being formed in such a manner that the rotation limiting part overlaps the interlocking member guide path when the second body slides or is closed.

It is preferable that a rotation torsion spring for providing torsion force to the rotation axis member is installed between the rotational axis member and the first body, and a sliding torsion spring for providing elastic force in a direction where the second body slides is installed between the second body and the guide member.

It is preferable that a hole is formed at the first body, the rotation axis member includes a supporting part, which is locked in an edge of the hole so as to be rotatably supported by the first body, and a guide member assembling part protruding toward a side opposite to the supporting part through the hole so as to be assembled with the guide member, and a through hole for allowing an FPC connector to pass through the through hole is formed at the rotation axis member and the guide member.

The first body and the second body may be a linear shape or may be a curved shape as the case may be.

A sliding/rotation opening/closing module according to the present invention includes: a first body connection part; a guide member, which is rotatably installed at the first body connection part through a rotation axis member and has a slide guide part; an interlocking member, which is installed between the first body connection part and the guide member, and interlocks relative movements between the first body connection part and the guide member in a section where a position of the interlocking member respective to the first body connection part and the guide member changes according to each operation of the first body connection part and the guide member when the guide member rotates; and a link device, which is installed between the guide member and the second body or between the guide member and the second body connection part, and has one side connected with the interlocking member, the link device being folded or unfolded while the link device is rotated by the interlocking member when the guide member rotates so as to allow the second body or the second body connection part to slide, so that a position of the second body or the second body connection part respective to the guide member changes, wherein the sliding/rotation opening/closing module is installed in a portable electronic device in such a manner that it is positioned between a first body and a second body or the second body connection part so as to allow the second body to be opened/closed by a sliding and rotating operation respective to the first body.

It is preferable that a slide limitation guide path is arranged on the first body connection part along a periphery of the rotation axis member and has a section where distance from the slide limitation guide path to a rotational center of the rotation axis member changes so that the slide limitation guide path restictively allows the second body connection part to slide along the guide member in such a manner that the slide limitation guide path restrictively moves the interlocking member while allowing the guide member to rotate when the guide member performs a rotational movement.

Also, an interlocking member guide path is formed at the guide member along a route having at least one portion intersected with the slide limitation guide path when the guide member rotates, and allows a position of the interlocking member respective to the first body connection part and the guide member to change in a state where the interlocking member is interlocked.

It is preferable that the rotation axis member is installed at the first body connection part in such a manner that it is deviated toward a right side or a left side of an upper end of the first body connection part, and a degree of a change in a distance between the slide limitation guide path and the rotational center of the rotation axis member in the section has been determined so as to allow the second body or the second body connection part to slide along the slide guide part while rotating about the rotation axis member, thereby adjusting a transverse center of the second body or the second body connection part with respect to the first body connected with the first body connection part, when the second body or the second body connection part is opened through rotation.

In this case, it is preferable that the first body connection part has a rotation limiting part formed along a route, which prevents or restrictively allows rotation of the second body or the second body connection part while allowing the second body or the second body connection part to slide in performing a sliding operation.

It is preferable that the link device includes a first link member rotatably installed at the guide member and a second link member, which is rotatably connected with the first link member and will be rotatably supported by the second body, and the interlocking member is connected with one side of the first link member.

Also, it is preferable that the rotation limiting part is connected with one end of the slide limitation guide path, the rotation limiting part having a circular arc-shape having a center corresponding to a rotational center of the link device, and being formed in such a manner that the rotation limiting part overlaps the interlocking member guide path when the second body or the second body connection part slides or is closed.

Similarly, it is preferable that the link device includes a first link member rotatably installed at the guide member, a second link member, which is rotatably connected with the first link member and will be rotatably supported by the second body, and a third link member, which is rotatably installed at one side of the first link member and has one side connected with the interlocking member.

Also, it is preferable that the rotation limiting part is connected with one end of the slide limitation guide path, shaped by a curved line or a linear line, and formed in such a manner that the rotation limiting part overlaps the interlocking member guide path when the second body slides or is closed.

It is preferable that a rotation torsion spring for providing torsion force to the rotation axis member is installed between the rotational axis member and the first body connection part, and a sliding torsion spring for providing elastic force in a direction where the second body or the second body connection part slides is installed between the second body and the guide member or between the second body connection part and the guide member.

It is preferable that a hole is formed at the first body connection part, the rotation axis member includes a supporting part, which is locked in an edge of the hole so as to be rotatably supported by the first body connection part, and a guide member assembling part protruding toward a side opposite to the supporting part through the hole so as to be assembled with the guide member, and a through hole for allowing a FPC connector to pass through the through hole is formed at the rotation axis member and the guide member.

The first body connection part and the second body or the second body connection part may have a linear shape or a shape curved in a transverse direction.

A first body, which is a part used for a portable electronic device according to present invention, preferably includes: a slide limitation guide path, which is formed along a periphery of a rotation axis member installation part and has a section where distance from the slide limitation guide path to a rotational center of the rotation axis member changes so as to allow an interlocking member interlocked with the slide limitation guide path to be restrictively moved while allowing rotation of a guide member when the guide member rotatably installed through the rotation axis member rotates, so that the slide limitation guide path restrictively allows a second body slidably installed at the guide member to slide along the guide member, and a rotation limiting part, which prevents or restrictively allows rotation of the second body while allowing the second body to slide when the second body performs a sliding operation.

A first body connection part, which is a part used for a portable electronic device according to present invention, preferably includes: a slide limitation guide path, which is formed along a periphery of a rotation axis member installation part and has a section where distance from the slide limitation guide path to a rotational center of the rotation axis member changes so as to allow an interlocking member interlocked with the slide limitation guide path to be restrictively moved while allowing rotation of a guide member when the guide member rotatably installed through the rotation axis member rotates, so that the slide limitation guide path restrictively allows a second body connection part slidably installed at the guide member to slide along the guide member; and a rotation limiting part, which prevents or restrictively allows rotation of the second body connection part while allowing the second body connection part to slide when the second body connection part performs a sliding operation.

As the case may be, a pair of slide guide parts may be installed at left and right sides of the guide member respectively, and a pair of guided slide parts, which is assembled with the slide guide parts to be guided, may be installed at left and right sides of the second body respectively.

As the case may be, the guide member may be installed in such a manner that the guide member can be tilted respective to the first body.

In addition, the first body may have a tilting part, which can be bent in an upper direction, and the guide member may be installed at the tilting part.

A pair of slide guide parts may be installed at left and right sides of the guide member respectively, and a pair of guided slide parts, which is assembled with the slide guide parts to be guided, may be installed at left and right sides of the second body or the second body connection part respectively.

A portable electronic device according to the present invention includes: a first body; a tilting part, which is tiltably installed at an upper end of the first body, and can be raised in such a manner that it is bent in an upper direction and can be again unfolded in a state where the tilting part has been bent to be raised; a guide member, which is installed at the tilting part and has a slide guide part; and a second body slidably installed at the slide guide part.

Also, the second body can be bent at an acute angle respective to the first body in a state where the second body is opened through sliding.

In addition, the guide member is installed at the tilting part in such a manner that the guide member can rotate about a rotation axis member.

Also, the second body may have a structure where the second body can be bent at an acute angle respective to the first body in a state where the second body is opened through rotation.

As the case may be, a portable electronic device according to the present invention may include: a first body; a tilting part, which is tiltably installed at an upper end of the first body, and can be raised in such a manner that it is bent in an upper direction and can be again unfolded in a state where the tilting part has been bent to be raised; and a second body rotatably installed at the tilting part.

The second body may have a structure where the second body can be bent at an acute angle respective to the first body in a state where the second body is opened through rotation.

### BRIEF DESCRIPTION OF THE DRAWINGS

The above and other objects, features and advantages of the present invention will be more apparent from the following detailed description taken in conjunction with the accompanying drawings, in which:

FIG. 1 is a perspective view of a sliding/rotation opening/closing portable electronic device according to the present invention;

FIG. 2 is an exploded perspective view of the sliding/rotation opening/closing portable electronic device of FIG. 1;

FIG. 3 is an exploded perspective view of the sliding/rotation opening/closing portable electronic device of FIG. 2, in which parts of the portable electronic device are reversed;

FIGS. 4 to 6 are planes of the sliding/rotation opening/closing portable electronic device, in which a state of a second body being closed, a state of the second body being rotated, and a state of the second body is opened after rotation are shown, respectively;

FIGS. 7 to 9 are rear views of the sliding/rotation opening/closing portable electronic device, in which the state of a second body being closed, the state of the second body being rotated, and the state of the second body is opened after rotation are shown, respectively;

FIG. 10 is a plane showing a state where the second body is opened through sliding;

FIG. 11 is a rear view showing the state where the second body is opened through sliding;

FIG. 12 is an exploded perspective view of a sliding/rotation opening/closing portable electronic device according to another embodiment of the present invention;

FIG. 13 is an exploded perspective view of the sliding/rotation opening/closing portable electronic device of FIG. 12, in which upper and lower sides of the device are reversed;

FIG. 14 is a view illustrating a modified example of a sliding/rotation opening/closing portable electronic device according to the present invention;

FIG. 15 is a view illustrating a modified example of the sliding/rotation opening/closing portable electronic device of FIG. 14;

FIG. 16 is an exploded perspective view of a sliding/rotation opening/closing module according to the present invention;

FIG. 17 is an exploded perspective view of a sliding/rotation opening/closing module, in which a second body connecting part is further included in the module of FIG. 16;

FIG. 18 is a view illustrating a portable electronic device according to another embodiment of the present invention;

FIG. 19 is an exploded perspective view of the portable electronic device of FIG. 18;

FIG. 20 is an exploded perspective view of the portable electronic device of FIG. 19, in which a bottom surface is shown;

FIG. 21 is a view illustrating a state where the portable electronic device of FIG. 18 is opened through sliding;

FIG. 22 is a view illustrating the portable electronic device, in which a state of the second body being rotated at approximate 90 degrees in the state of FIG. 21 is shown;

FIG. 23 is a perspective view of the portable electronic device, in which a state of the second body being tilted in the state of FIG. 21 is shown;

FIG. 24 is a perspective view of the portable electronic device, in which a rear surface of the device is shown;

FIG. 25 is a side view of the portable electronic device of FIG. 23; and

FIG. 26 is an exploded perspective view of a modified example of the portable electronic device of FIG. 2.

### DETAILED DESCRIPTION OF THE PREFERRED EMBODIMENTS

Hereinafter, preferred embodiments of the present invention will be described with reference to the accompanying drawings.

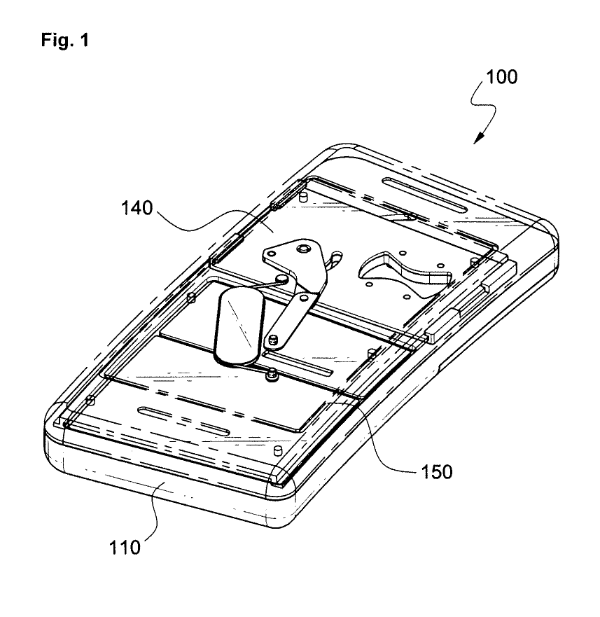

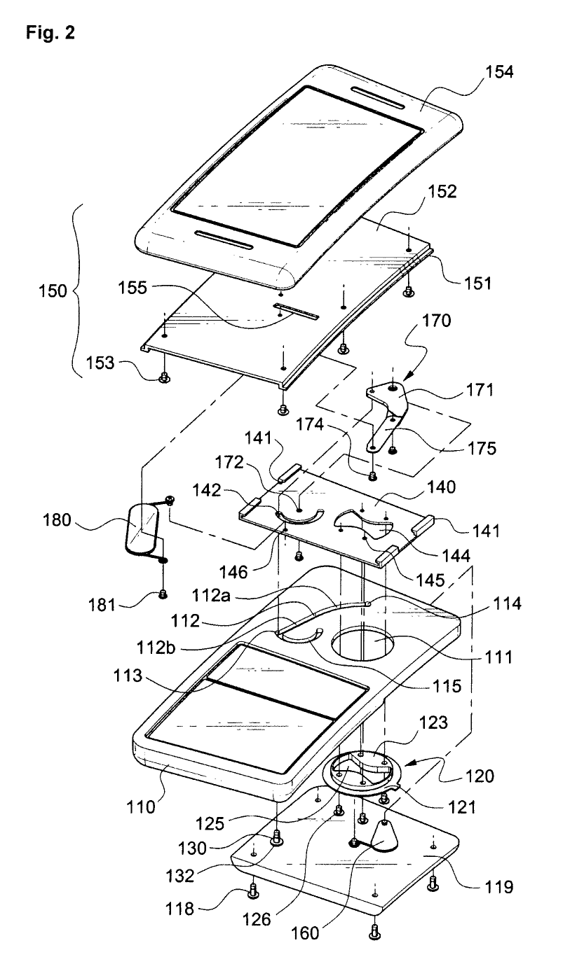

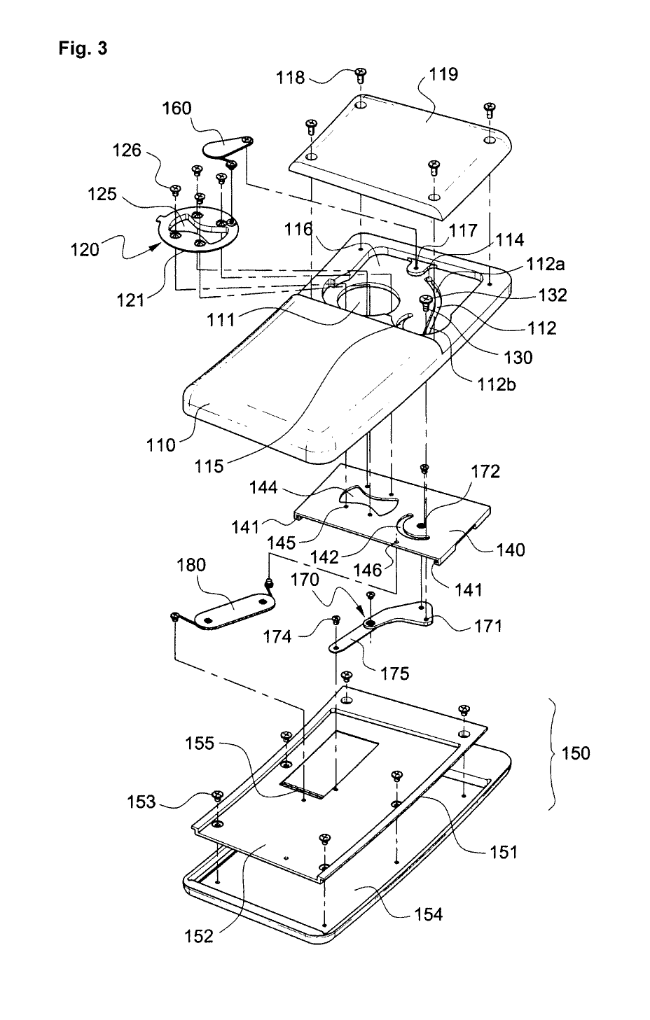

FIG. 1 is a perspective view of a sliding/rotation opening/closing portable electronic device according to the present invention, FIG. 2 is an exploded perspective view of the portable electronic device of FIG. 1, and FIG. 3 is an exploded perspective view of the portable electronic device of FIG. 2, in which parts of the portable electronic device are reversed.

As shown in FIG. 1 to 3, the sliding/rotation opening/closing portable electronic device 100 according to the present invention includes a first body 110. The first body 110 is a main body of the portable electronic device 100 and a part where a substrate having various parts and input keys, etc. are mainly installed thereon.

As shown, the first body 110 has a hole 111 of a circular shape for installation of a rotation axis member 120, and the rotation axis member 120 is installed in the hole 111 in such a manner that it can rotate from a fixed position. As shown in FIGS. 2 and 3, there is no need to form the hole 111 in a large size. This is because if the hole can support the rotation axis member 120 in such a manner that it can rotate from a fixed position, it is sufficient.

As shown in FIGS. 2 and 3, the first body 110 has a slide limitation guide path 112 formed along the hole 111, in which the rotation axis member 120 is installed. The slide limitation guide path 112 is interlocked with an interlocking member 130, which will be described below. Therefore, the slide limitation guide path 112 allows rotation of the guide member 140 and allows the interlocking member 130 to restrictively move when the guide member 140 performs a rotation movement so that the slide limitation guide path 112 restrictively allows a second body 150 to slide along the guide member 140. In order to achieve this, the slide limitation guide path 112 has a section 112a where distance from the slide limitation guide path to a rotational center of the rotation axis member 120 changes. In a section 112b where distance from the slide limitation guide path to the rotational center of the rotation axis member 120 doesn't change, the position of the interlocking member 130 respective to the guide member 140 isn't changed. In order to increase a sliding distance of the second body 150 respective to the guide member 140, it is enough to increase the length of the section where distance from the slide limitation guide path to the rotational center of the rotation axis member 120 changes or to change distance from the slide limitation guide path to the rotational center respective to a rotation angle greatly.

In this section 112a, when the guide member 140 rotates about the rotation axis member 120, force is applied to the interlocking member 130 so that the position of the interlocking member 130 respective to the guide member 140 is moved.

Locking grooves 113 and 114 are formed at both ends of the slide limitation guide path 112, respectively. The locking grooves allow the user to recognize the fact that rotational operation of the second body 150 has been completed, and allows the second body to maintain its stable position at the both ends. Among these locking grooves, the locking groove 113 positioned at a lower end of the slide limitation guide path performs a function of allowing the second body 150 to slide upward a little and then perform a rotational operation. The locking groove 113 is useful in a case where a lower part of the first body 110 has a part which becomes an obstacle when the second body 150 rotates from a fixed position in a starting step of performing a rotational operation.

The first body 110 further includes a rotation limiting part 115. When the second body 150 performs a sliding movement, the rotation limiting part 115 prevents the second body 150 from rotating or allows it to be restrictively rotated while allowing the second body 150 to slide. The rotation limiting part 115 is shaped like a circular arc formed while centering one spot positioned at the periphery of the rotation axis member 120. When the interlocking member 130 is located at a part of the rotation limiting part 115, which corresponds to a tangent line respective to a concentric circle while having a center corresponding to a rotational center of the rotation axis member 120, the rotation limiting part 115 allows the second body 150 and the guide member 140 to rotate respective to the first body 110. The rotation limiting part 115 is preferably connected with the slide limitation guide path 112.

Referring to FIG. 3, a recess 116 is formed at a bottom surface of the first body 110, and a rotation torsion spring installation part 117, with which one end of a rotation torsion spring 160 for providing elastic force in a rotational direction, i.e. torsion force to the rotation axis member 120 is connected, is formed at an upper side of the recess 116. The recess 116 is covered by a cover material 119 assembled with the first body 110 by means of screw members 118.

The sliding/rotation opening/closing portable electronic device 100 according to the present invention includes the guide member 140 and the rotation axis member 120 supporting the guide member 140 in such a manner that the guide member can rotate on the first body 110. The rotation axis member 120 is assembled with the guide member 140 through screw members 126. In order to allow the second body 150 to be bent upward at a predetermined angle in a state where the second body has been slid or opened through rotation, it is possible that the upper end of the first body 110, which is assembled with the guide member 140, is connected with a main body positioned below through a hinge, etc. so as to have a structure in the shape of a tilting part.

The guide member 140 includes slide guide parts 141 so as to allow the second body 150 to slide. It is desirable that each slide guide part 141 is formed along both edges of the guide member. In the present embodiment, each slide guide part 141 has a groove-shape having an opened inner side. However, each slide guide part can also have a groove-shape having an opened outer side opposite to the above structure. As the case may be, each slide guide part can be shaped like a groove or a hole for guiding a shaft having a circle-sectional shape. An interlocking member guide path 142 is formed at one side of the guide member 140. The interlocking member guide path 142 is formed along a route having at least one part to be intersected with the slide limitation guide path 112 while the second body 150 rotates about the rotation axis member 120 to be opened. In a state where the interlocking member 130 is interlocked with the interlocking member guide path 142, the interlocking member guide path 142 allows a relative position of the interlocking member 130 respective to the first body 110 and the guide member 140 to be changed. The interlocking member guide path 142 is arranged in such a manner that it overlaps the rotation limiting part 115 formed at the first body 110 in a closed state so that a path allowing the interlocking member 130 to move is provided when the second body 150 slides. This interlocking member guide path 142 has a circular arc-shape having a center corresponding to a rotational center 172 of a first link member 171 of a link device 170, which will be described below.

A though hole 144, through which a flexible connector, such as an FPC, etc., can pass, is formed at a portion assembled with the rotation axis member 120, which neighbors the interlocking member guide path 142. It is preferable that the through hole 144 is shaped like a butterfly in consideration of movement of the flexible connector, such as an FPC, etc. Assembling holes 145 for connecting the rotation axis member 120 are formed at the periphery of the through hole 144. A torsion spring connection part 146, with which one end of a sliding torsion spring 180 is connected, is formed adjacent to the interlocking member guide path 142.

The sliding torsion spring 180, which provides elastic force to the second body 150 when the second body 150 slides to be opened, is installed between the guide member 140 and the second body 150.

The rotation axis member 120 includes a supporting part 121, which is locked in an edge of the hole 111 so as to be rotatably supported by the first body 110, and a guide member assembling part 123, which protrudes toward a side opposite to the supporting part 121 through the hole 111 so as to be assembled with the guide member 140. Also, a through hole 125 for allowing a flexible connector, such as an FPC, etc. to pass via the through hole is formed at the center of the rotation axis member 120.

A rotation torsion spring 160 is installed between the rotation axis member 120 and the first body 110. The rotation torsion spring 160 applies rotational force in a closing direction in a state of the second body 150 being closed, and applies rotational force in an opening direction in a state of the second body being opened.

The sliding/rotation opening/closing portable electronic device 100 according to the present invention includes the interlocking member 130. The interlocking member 130 is interlocked with the interlocking member guide path 142 and the slide limitation guide path 112 or the rotation limiting part 115, which have been described above, so as to allow the first body 110, the guide member 140, and the second body 150 to move while interlocking with each other according to rotation of the guide member 140 or sliding of the second body 150. The interlocking member 130 is installed between the first body 110 and the guide member 140 through the interlocking member guide path 142 and the slide limitation guide path 112 or the rotation limiting part 115 so that there is a section where a relative position of the interlocking member 130 respective to the first body 110 and the guide member 140 changes according to the operation of the first body 110 and the guide member 140 when the guide member 140 rotates. A head part 132 of the interlocking member 130 is locked in the corner of the slide limitation guide path 112 or the rotation limiting part 115, which is formed on the first body 110, so as to prevent the guide member 140 from releasing from the first body 110. Accordingly, the guide member 140 has a stable assembling structure in such a manner that it is supported by the first body 110 through two elements, i.e. the rotation axis member 120 and the interlocking members, 130. Also, the guide member 140 prevents one side of the second body 150 installed at the guide member 140 from being spaced from the first body 110, and allows the one side to endure serious impact.

The sliding/rotation opening/closing portable electronic device 100 according to the present invention includes the link device 170. The link device 170 includes the first link member 171 installed at the guide member in such a manner that is can rotate from a fixed position and a second link member 175, which has one end rotatably connected with the first link member 141 and the other end rotatably connected with the second body 150. The interlocking member 130 is assembled with one side of the first link member 141. Accordingly, when the second body 150 moves along the slide guide part 141 of the guide member 140, or the guide member 140 rotates about the rotation axis member 120, the link device 170 is unfolded or folded while rotating about its supporting spot 172. The interlocking member 130 connected with the first link member 171 moves along the interlocking member guide path 142 and the rotation limiting part 115 when the second body 150 slides, and moves along the interlocking member guide path 142 and the slide limitation guide path 112 when the second body 10 performs a rotational movement.

The link device 170 is installed between the guide member 140 and the second body 150. The link device 170 is folded or unfolded by while rotating about a supporting spot by the interlocking member 130 when the guide member 140 rotates so as to pull the second body 150 toward the guide member 140 or push the second body to slide toward a side opposite to the guide member, thereby changing a relative position of the second body 150 respective to the guide member 140.

At this time, the interlocking member 130 receives force at a part where distance from the slide limitation guide path 112 to the rotational center of the rotation axis member 120 changes, and rotates the first link member 171. While the second link member 175 is rotated as the first link member 171 is rotated, the link device 170 is folded or unfolded.

Accordingly, the second body 150 restrictively slide along the slide guide part 141 of the guide member 140 while rotating together with the guide member 140 so that the center of the second body 150 respective to the first body 110 can be adjusted leftward or rightward when the second body is completely opened. Of course, there is no need for adjusting the center of the second body 150 leftward or rightward respective to the first body 110 when the second body 150 is rotated to be opened.

As such, the second body 150 slides respective to the guide member 140 when it rotates to be opened so that a transverse position of the second body can be adjusted leftward or rightward. As a result, the rotation axis member 120 can be moved from an edge of the first body 110 to the inner side thereof, or as the case may be, can be moved to a further upper side in comparison with its position of a conventional portable electronic device to be installed. Accordingly, the sliding/rotation opening/closing portable electronic device 100 according to the present invention can be designed without any limitation, and a connection structure between the first body 110 and the second body 150 is stable. Also, it is possible to secure a large area for installation of keys, etc. on the first body 110.

The sliding/rotation opening/closing portable electronic device 100 according to the present invention includes the second body 150. The second body 150 is a part which has a displayer, such as an LCD, etc., typically installed thereon, and can slide and rotate respective to the first body 110. The second body 150 includes a guide jaw 151, which is assembled with the slide guide part 141 and is guided, and has one side connected with the other end of the link device 170. The second body 150 can have an auxiliary member 152 so as to easily form the guide jaw 151. The auxiliary member 152 is assembled with a main body 154 of the second body 150 through screw members 153. In this case, a slot 155 has to be formed at the auxiliary member 152 so as to allow the flexible connector to pass through the slot. Of course, the guide jaw 151 is directly formed at a bottom surface of the second body 150, and in this case, the auxiliary member 152 isn't necessary.

The sliding/rotation opening/closing portable electronic device 100, which has been illustrated above, has a shape bent in left and right sides. Also, the first body 110, the guide member 140, and the second body 150, which are included in the device, also have a bent shape. However, it is also possible for them to have a linear shape, which isn't bent in left and right sides.

Elements indicated with non-described numeral references 174 and 181 are rotational supporting members for supporting a torsion spring and a link member in such a manner that the rotational supporting members rotatably connect them with each other at a necessary position.

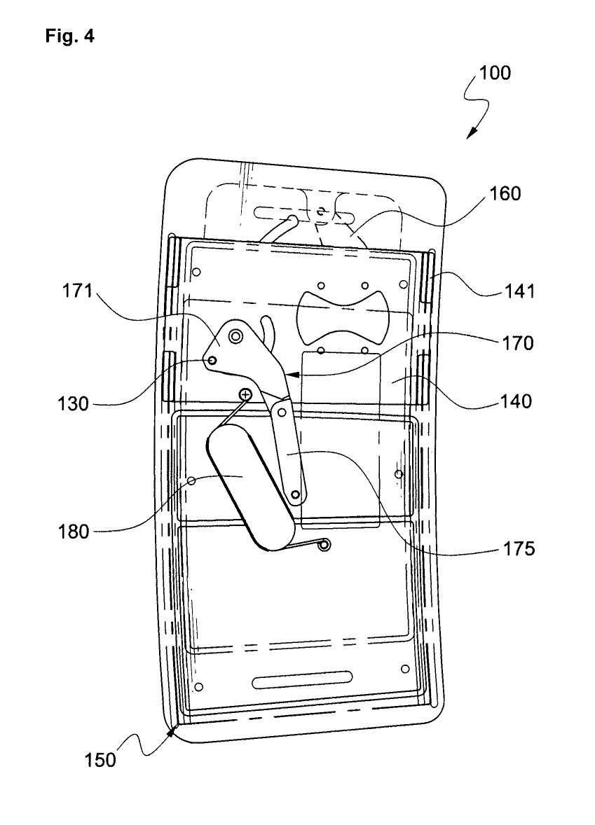

The operational processes of the sliding/rotation opening/closing portable electronic device 100 according to the present invention when it is opened through rotation will be described below with reference to FIGS. 4 to 9.

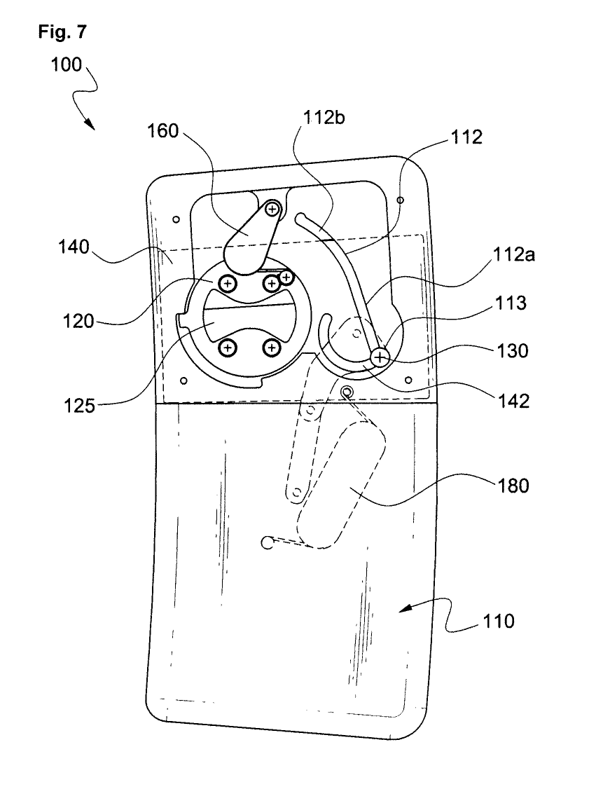

FIGS. 4 to 6 are planes of the portable electronic device, in which a state of a second body being closed, a state of the second body being rotated, and a state of the second body is opened after rotation are shown, respectively, and FIGS. 7 to 9 are rear views of the above respective states.

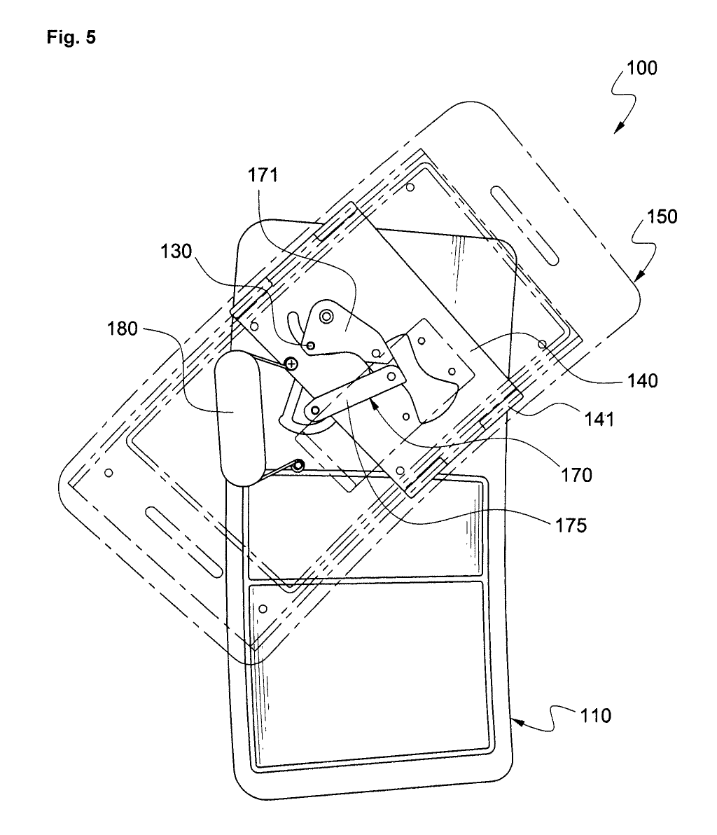

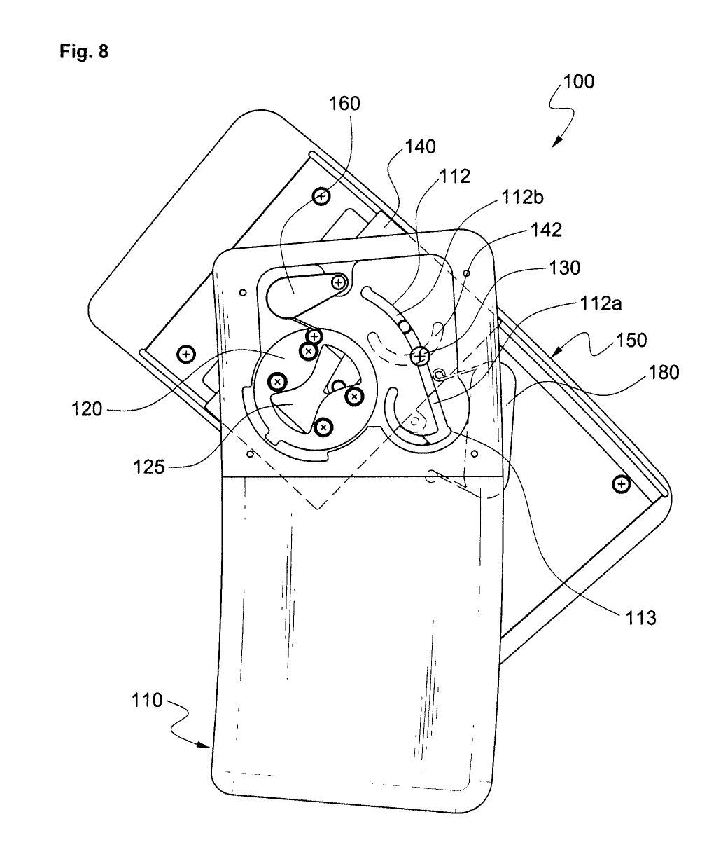

In a state where a user grasps the sliding/rotation closing/opening portable electronic device 100, which is in a closed state as shown in FIGS. 4 and 7, if the user pushes a lower end of a right side of the second body 150 in a left direction, while the interlocking member 130 escapes from the locking groove 113, the second body 150 and the guide member 140, which supports the second body 150 in such a manner that it can slide, rotate in a clockwise direction about the rotation axis member 120. Accordingly, the interlocking member 130 is forced toward the rotation axis member 120 through the slide limitation guide path 112a, which is a section where distance from the slide limitation guide path to the rotational center of the rotation axis member 120 changes so that the interlocking member 130 moves in a direction where it becomes near by the rotation axis member 120 along the interlocking member guide path 142 formed on the guide member 140. In such a procedure, the interlocking member moves along a position where the slide limitation guide path 112 and the interlocking member guide path 142 are intersected with each other. As such, the state where the second body 150 is rotated respective to the first body 110 at 45 degrees is shown in FIGS. 5 and 8.

As the interlocking member 130 moves, while the first link member 171 of the link device 170 rotates about its supporting spot in a counterclockwise direction, the first link member 171 pulls the second link member 175 so as to allow the link device 170 to be folded. Accordingly, the second body 150 connected with the second link member 175 rotates and simultaneously slides along the slide guide part 141 of the guide member 140. Such an operation is performed while the interlocking member moves in the section where the distance from the slide limitation guide path to the rotational center of the rotation axis member 120 changes. This can be understood if the position of the second body 150 respective to the guide member 140, which is shown in FIGS. 4 and 7, is compared with the position of the second body 150 respective to the guide member 140, which is shown in FIGS. 5 and 8.

At this time, the rotation torsion spring 160, at first, applies elastic force in a direction where it is interrupted that the second body 150 rotates to be opened, and after the torsion spring 160 is completely retracted, the torsion spring 160 applies elastic force in a direction where the second body 150 rotates to be opened while the torsion spring 160 again extends.

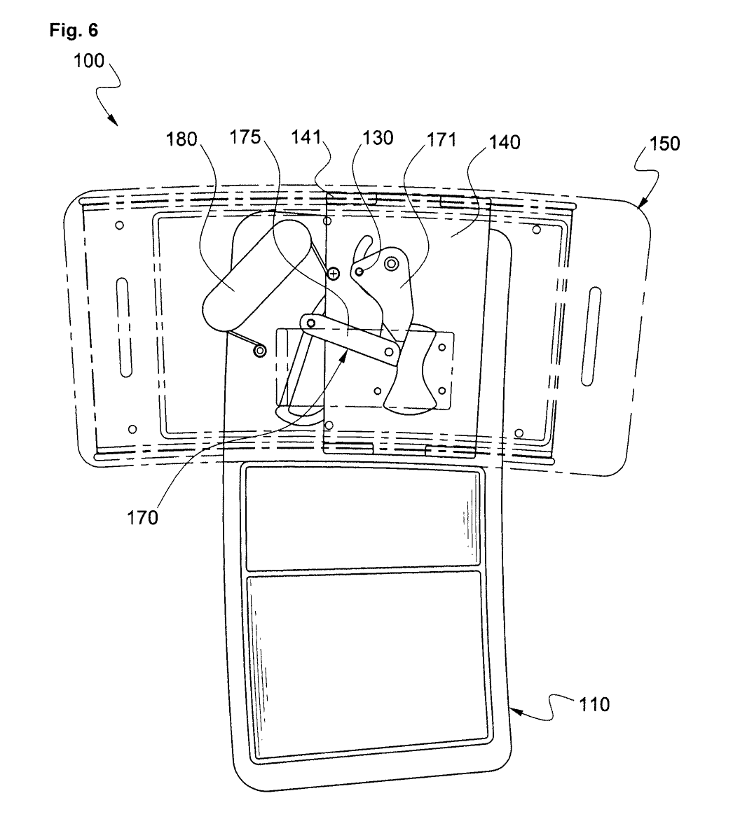

Also, the sliding torsion spring 180 is retracted as the second body 150 rotates. As shown in FIG. 6, in a state where the second body 150 is completely opened through rotation, the sliding torsion spring 180 applies force to push the second body 150 in a left direction respective to the guide member 140.

In a state where the second body 150 is preferably opened through rotation at an end point of the section where the distance from the rotational center of the rotation axis member 120 changes or at a starting point of the section 112b where the distance from the rotational center of the rotation axis member 120 doesn't change, the second body 150 maintains its location, at which the center of the second body 150 respective to the first body 110 has been adjusted leftward or rightward.

At the section where the distance from the slide limitation guide path to the rotational center of the rotation axis member 120 doesn't change, after the end point of the section where the distance from the slide limitation guide path to the rotational center of the rotation axis member 120 changes, the slide limitation guide path 112 doesn't allow the interlocking member 130 to move any more so that the link device 170 maintains its current state. Therefore, the second body 150 stops the sliding operation and performs only a rotational operation.

Of course, it is also possible to arrange the slide limitation guide path 112 in such a manner that distance from the slide limitation guide path to the rotational center of the rotation axis member 120 changes along whole section of the slide limitation guide path so that the second body 150 can perform a rotation operation as well as a sliding operation in the whole section of the slide limitation guide path.

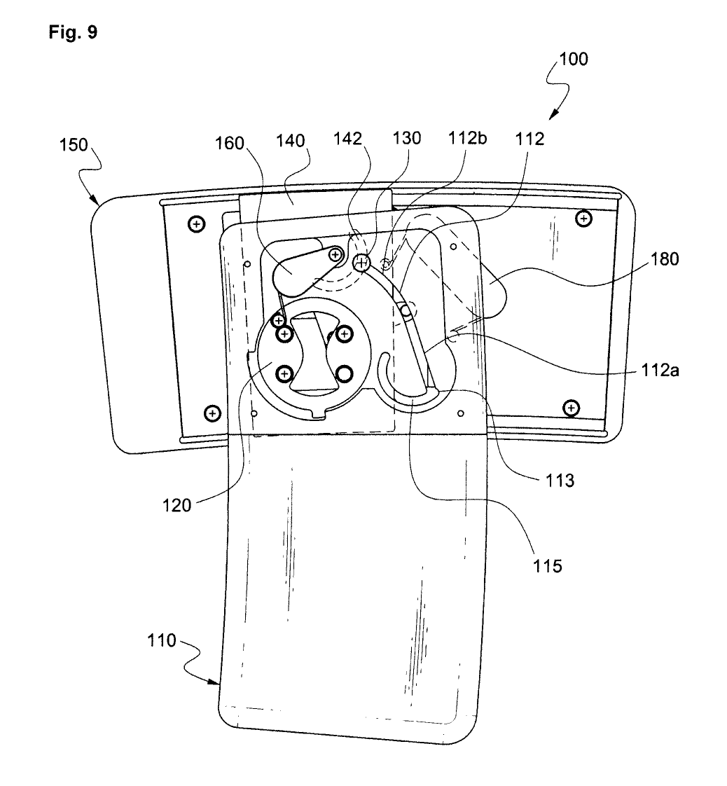

As such, the operational state of each part of the portable electronic device in a state where the second body is opened through rotation is shown in FIGS. 6 and 9.

Referring to FIG. 6, the sliding torsion spring 180 applies elastic force to the second body 150 in a left direction respective to the guide member 140, and the link device 170 keeps a folded state allowing the second body 150 to be positioned at the center of the first body 110 in a transverse direction. Referring to FIG. 9, in a state where the rotation torsion spring 160 is retracted, the rotation torsion spring 160 applies elastic force in a direction where the second body 150 is opened. The interlocking member 130 is positioned at an upper end of the slide limitation guide path 112 and is also positioned at a middle portion of the interlocking member guide path 142. In this state, the second body 150 rotates at about 90 degrees in comparison with an initial state thereof so that the second body 150 is arranged in a transverse direction in such a manner that the center of the second body 150 respective to the first body 110 is adjusted leftward or rightward. In this state, the second body 150 cannot slide in a direction of the slide guide part 141 of the guide member 140 because the slide limitation guide path 112 catches the interlocking member 130.

As shown in FIGS. 6 and 9, in a state where the second body 150 is opened through rotation, the second body 150 is again closed according a reverse procedure respective to the procedure where the second body is opened through rotation.

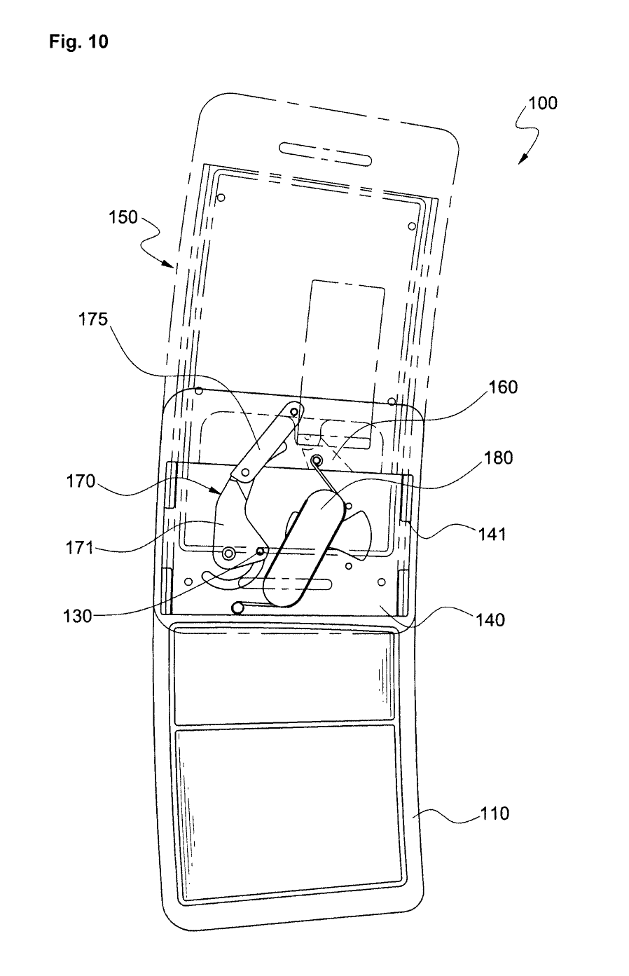

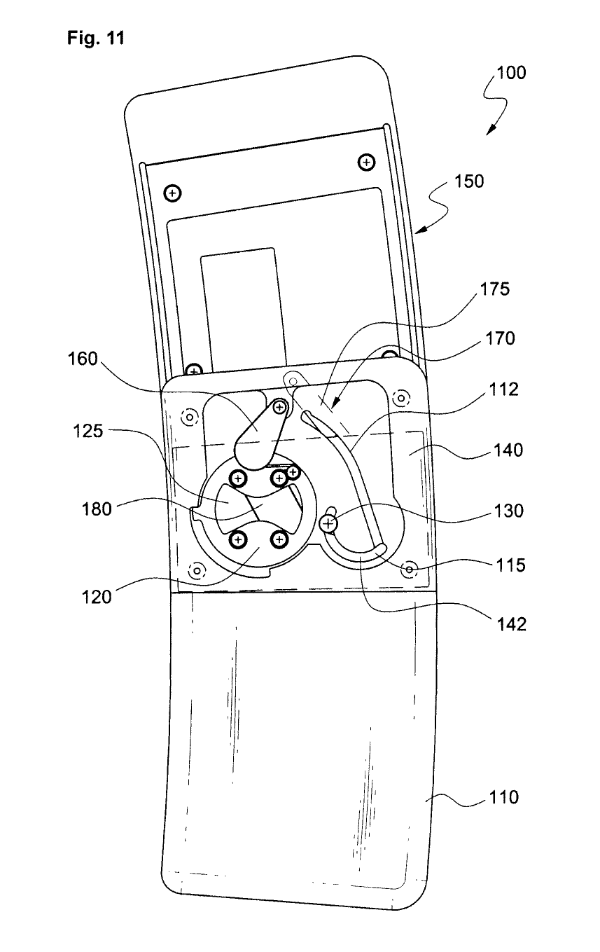

FIG. 10 is a plane showing a state where the second body is opened through sliding, and FIG. 11 is a rear view showing the state where the second body is opened through sliding.

With reference to FIG. 4, if the user grasps the sliding/rotation opening/closing portable electronic device 100 in the state shown in FIG. 4 by his/her hand and pushes the second body 150 upward, the second body 150 moves upward along the slide guide part 141 of the guide member 140. Also, while the second link member 175 of the link device 170, which has one end connected with the second body 150, moves upward along the second body 150, the second link member 171 allows the first link member 171 to rotate so that the link device 170 is folded. Accordingly, the first link member 171 rotates around its supporting point. Therefore, while the interlocking member 130 connected to one side of the first link member moves along the rotation limiting part 115 and the interlocking member guide path 142, which overlap each other, the interlocking member 130 allows the first link member 171 to rotate, and prevents the second body 150 from rotating or allows the second body 150 to restrictively rotate. The restrictive rotation of the second body 150 is performed at a portion where a tangent line is formed by a circle having the rotational center of the rotation axis member 120 as a center and the rotation limiting part 115. As such, if such a portion corresponding to the tangent line is formed at a position where the second body 150 is completely opened through sliding, this portion can perform a buffering function respective to impact force applied to both side surfaces of the second body.

At this time, the sliding torsion spring 180 applies elastic force in a direction where the second body 150 is closed at early stage. As the second body 150 is slid upward, the sliding torsion spring 180 gradually retracts and again extends after the second body passes by a predetermined section so as to apply elastic force in a direction where the second body 150 is opened.

As such, the state where the second body 150 is opened through sliding is shown in FIGS. 10 and 11. As shown in FIGS. 10 and 11, in a state where the second body 150 is opened after sliding, the link device 170 and the sliding torsion spring 180 have been folded upside, and the interlocking member 130 has been moved upside along the rotation limiting part 115 and the interlocking member guide path 142.

When the second body 150 is opened through sliding, the rotation axis member 120 and the rotation torsion spring 160 do not move. Also, the slide limitation guide path 115 does not give any affect on the interlocking member 130. The second body 150 is closed through sliding according to an inverse procedure respective to the procedure where the second body is opened through sliding. It is possible to see a state where the second 150 is completely closed with reference to FIGS. 4 and 7.

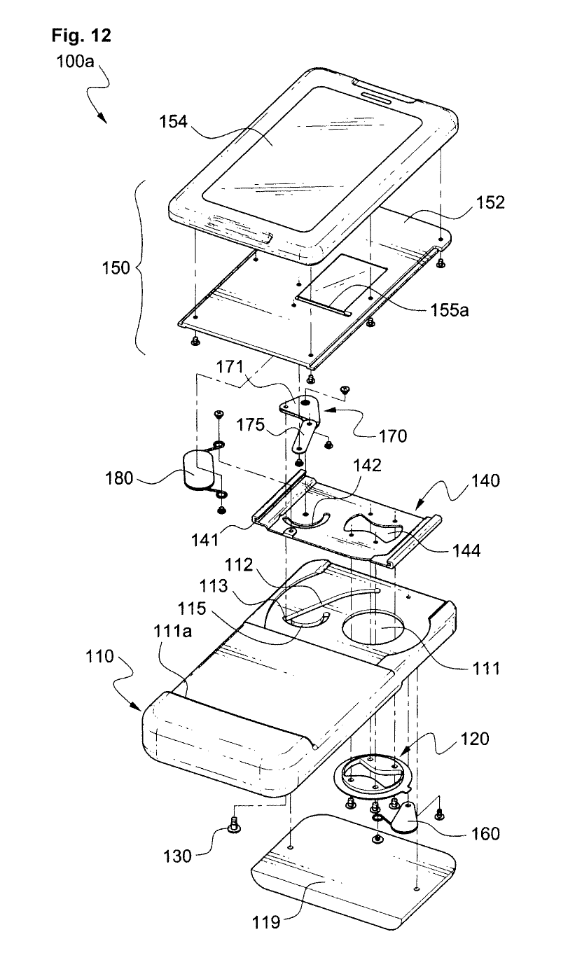

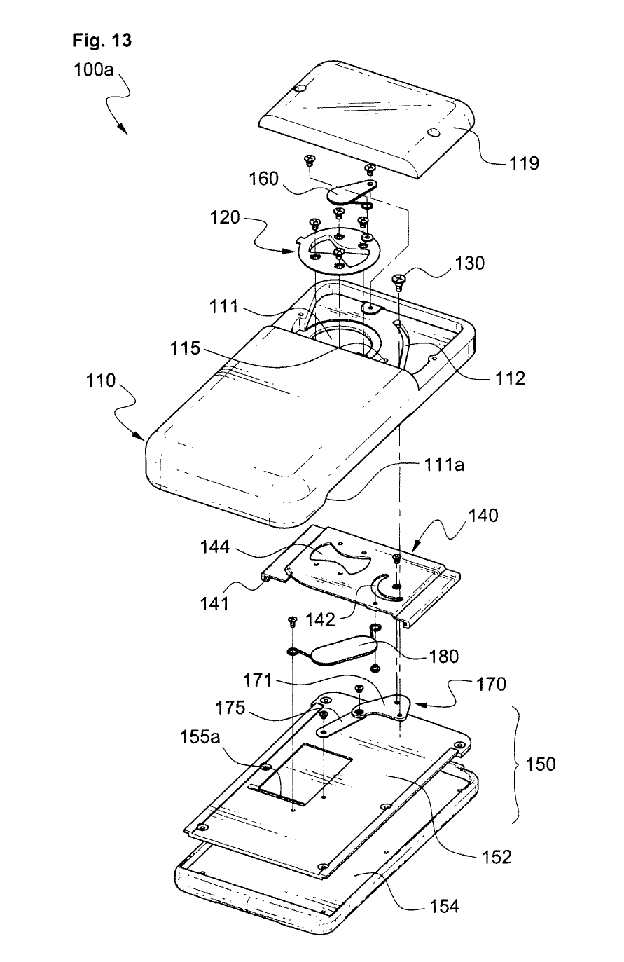

FIG. 12 is an exploded perspective view of a sliding/rotation opening/closing portable electronic device according to another embodiment of the present invention, and FIG. 13 is an exploded perspective view of the portable electronic device of FIG. 12, in which upper and lower sides of the device are reversed.

In comparison with the above described embodiment, the sliding/rotation opening/closing portable electronic device 100a, which is shown in FIGS. 12 and 13, has a difference in that the first body 110, the second body 150, and the guide member 140 have a linear shape, a jaw part 111a is formed at a lower end of the first body 110, and a recess is formed at a slot 155a of the auxiliary member 152 of the second body 150. Except for the difference, the remaining structure of the device is equal to the structure of the embodiment described in FIGS. 1 to 11.

Although the sliding/rotation opening/closing portable electronic device 100a according to the present invention has the jaw part 111a formed at the lower end of the first body 110 as shown in FIGS. 12 and 13, if a locking groove 113 is formed at a lower end of the slide limitation guide part 112, the second body 150 is rotated through sliding a little upward along the guide member 140 while the interlocking member 130 escapes the locking groove 113. As a result, the corner of the lower end of a right side of the second body 150 can rotate about the rotation axis member 1120 without locking in the jaw part 111a. The remaining operation is equal to the operation described through FIGS. 1 to 11.

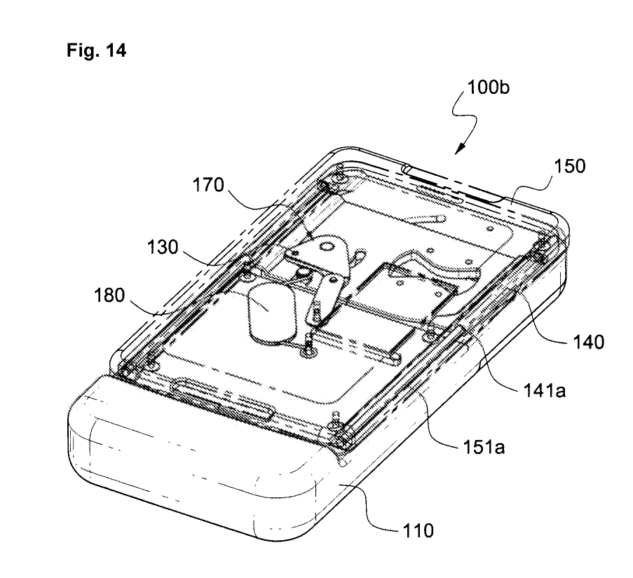

FIG. 14 is a view illustrating a modified example of a sliding/rotation opening/closing portable electronic device according to the present invention. In the sliding/rotation opening/closing portable electronic device 100b according to the present invention, which is shown in FIG. 14, each slide guide part 141a of the guide member 140 is shaped like a hole formed along edges of both sides of the guide member 140. Each shaft 151a, which is assembled with the corresponding slide guide part 141a having a hole-shape, is installed at both sides of the first body 10. As such, the sliding/rotation opening/closing portable electronic device 100a according to the present invention is structured. The remaining structure of the device is equal to the structure described through FIGS. 12 and 13.

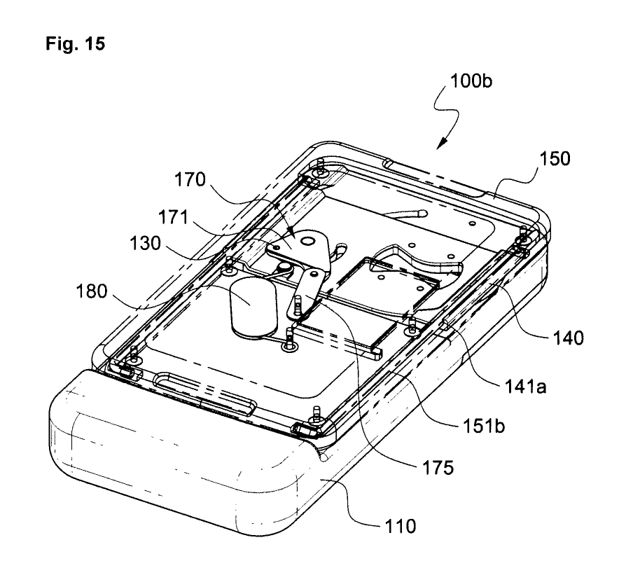

FIG. 15 is a view illustrating a modified example of the sliding/rotation opening/closing portable electronic device of FIG. 14.

Each slide guide part 141b is formed in such a manner that the slide guide part 141a installed at the guide member 140, which is shown in FIG. 14, has an opened inner side. Each shaft 151b is installed at edges of both sides of the second body 150 so that that the shaft 151b can be assembled with the corresponding slide guide part 141b to be slid. Also, the lower end of each shaft 151b can have a shape bent inside. The remaining structure of the device is shown in FIG. 14.

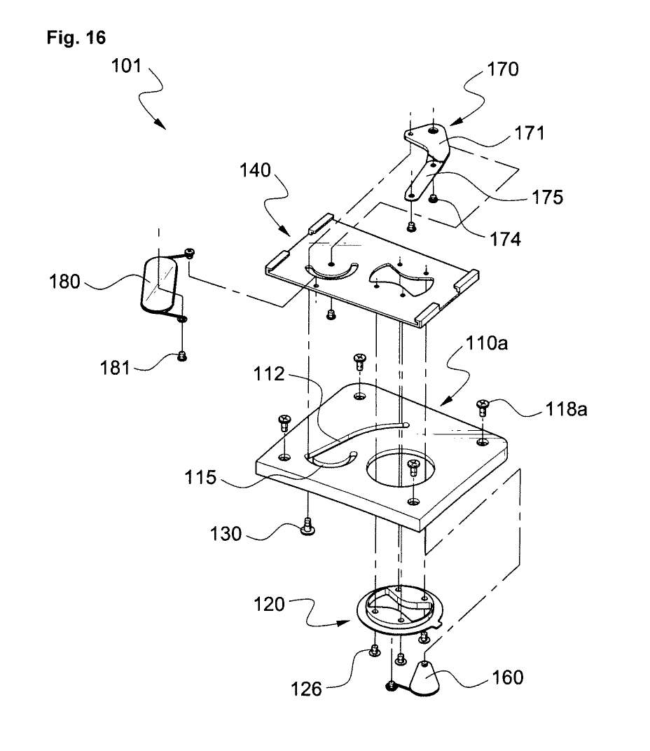

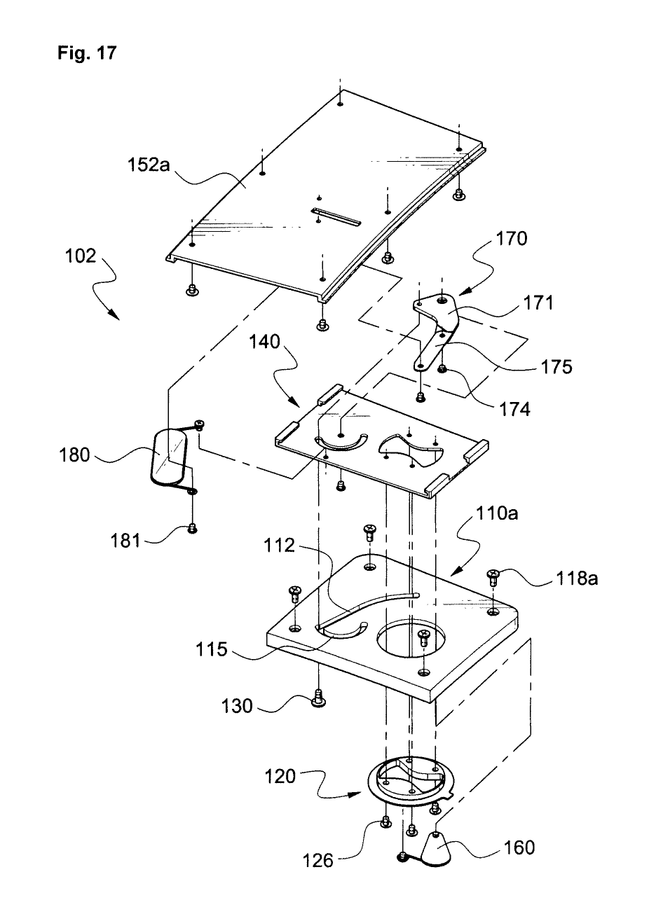

FIG. 16 is an exploded perspective view of a sliding/rotation opening/closing module according to the present invention, and FIG. 17 is an exploded perspective view of a sliding/rotation opening/closing module, in which a second body connecting part is further included in the module of FIG. 16.

As shown in FIGS. 16 and 17, as the case may be, it is possible that the slide limitation guide path 112 and the rotation limiting part 115, which have been described above, are not formed on the first body 110 of the portable electronic device, and the slide limitation guide path 112 and the rotation limiting part 115 are formed on a first body connection part 110a, which can be assembled with the first body 110. Also, the sliding/rotation opening/closing module 102 can be structured by the guide member 140, the rotation axis member 120, the link device 170, and a second body connection part 152a without the second body 150.

In FIG. 17, the second body connection part 152a corresponds to the auxiliary member 152 illustrated in FIGS. 1 to 11, and as the case may be, can be assembled with the second body 150 so as to be a part of the second body 150. Therefore, as shown in FIG. 16, the second body connection part 152a can be separately circulated, and not included in the sliding/rotation opening/closing module 102 according to the present invention. Also, the sliding torsion spring 180 have one end connected with the guide member 140, and the rotation torsion spring 160 has one end connected with the rotation axis member 120, and the other end of the sliding torsion spring 180 and the other end of the rotation torsion spring 160 are in a free state. Also, when the sliding/rotation opening/closing module 102 according to the present invention is assembled between the first body 110 and the second body 150, each free end of the sliding torsion spring 180 and the rotation torsion spring 160 is connected with corresponding portions of the first body 110 and the second body 150. An element indicated with non-described numeral reference 130 is an interlocking member, elements indicated with numeral references 126 and 118a are screw members, and elements indicated with numeral references 174 and 181 are a torsion spring and a rotation supporting member for supporting a link member in such a manner that the link member is rotatably connected with a corresponding portion.

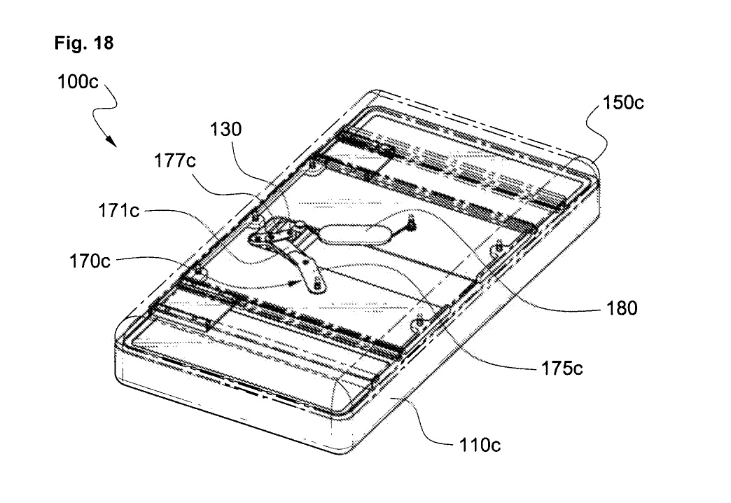

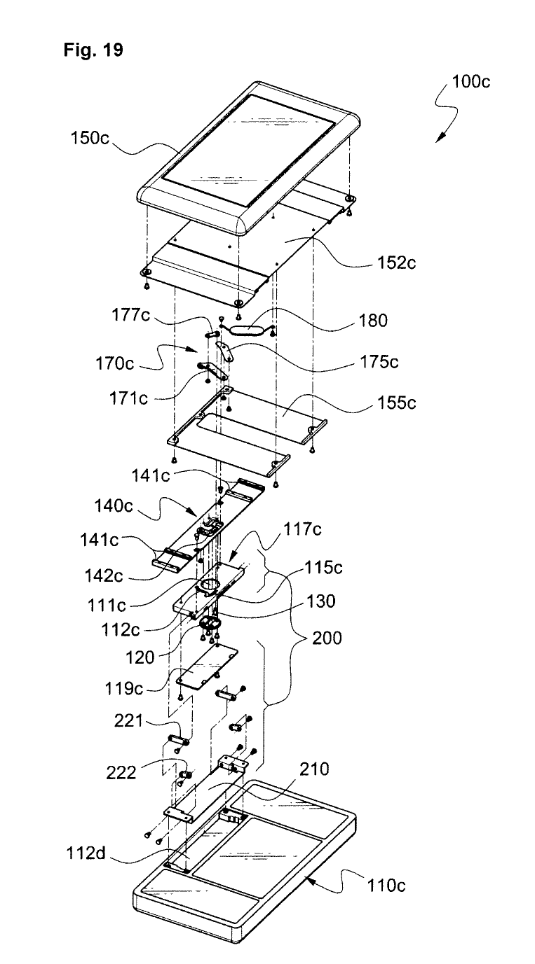

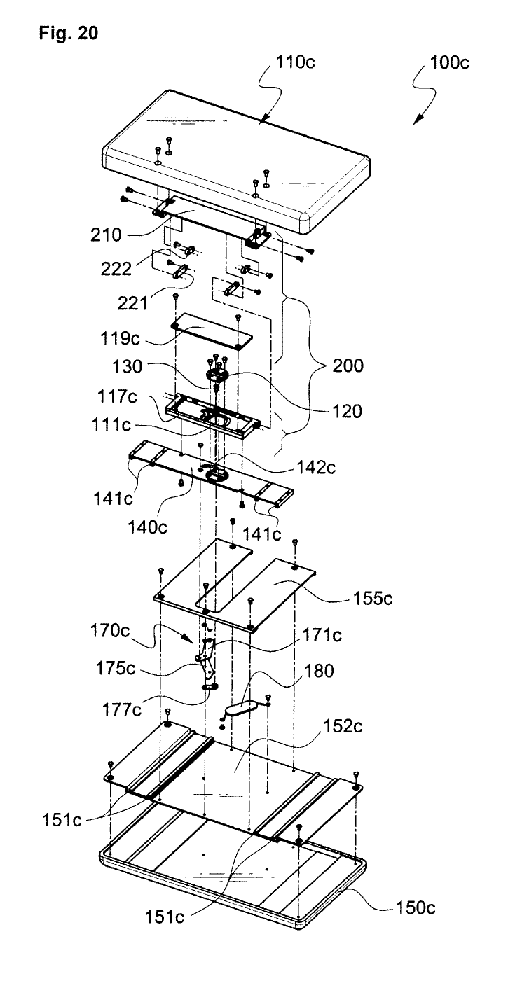

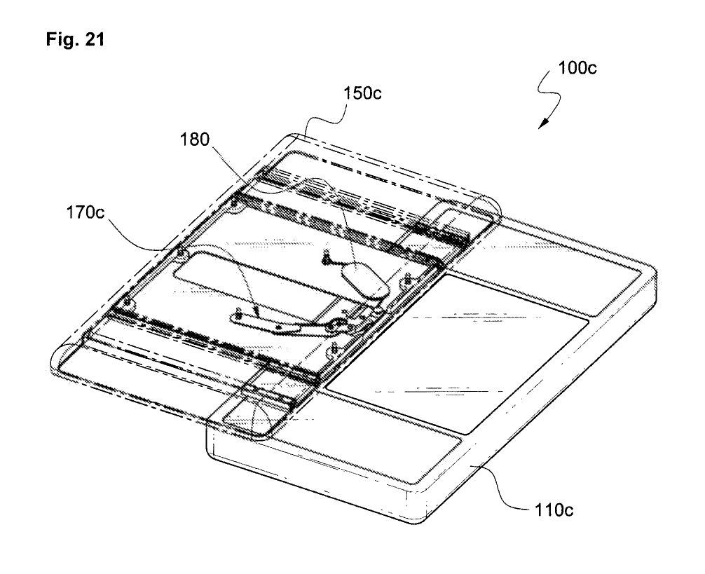

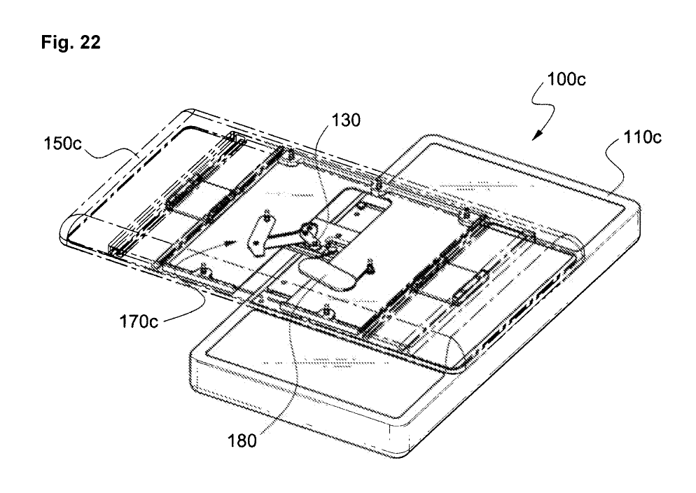

FIG. 18 is a view illustrating a portable electronic device according to another embodiment of the present invention, FIG. 19 is an exploded perspective view of the portable electronic device of FIG. 18, and FIG. 20 is an exploded perspective view of the portable electronic device of FIG. 19, in which a bottom surface is shown. Also, FIG. 21 is a view illustrating a state where the portable electronic device of FIG. 18 is opened through sliding, and FIG. 22 is a view illustrating the portable electronic device, in which a state of the second body being rotated at approximate 90 degrees in the state of FIG. 21 is shown.

As shown in FIGS. 18 to 22, the present invention can be applied to a portable electronic device 100c having a transverse width larger than a longitudinal length. As shown in FIGS. 18 to 22, a first body 110c and a second body 150c of the portable electronic device 100c according to the present invention have each a transverse width larger than a longitudinal length. A recess part 112d for installation of a tilting part 200 is formed at an upper end of the first body 110c. The tilting part 200 is installed on the recess part 112d.

The tilting part 200 includes a tilting link installation part 210 having both inner surfaces, which is stepped, and the tilting link installation part 210 may be integrally formed at the first body 110c. A pair of tilting links 221 and 222, each having a different length, is rotatably installed at the both inner surfaces of tilting link installation part 210, respectively. Although two pairs of tilting links 221 and 222 are described in the present embodiment, as the case may be, a pair of tilting links 221 and 222 is possible, and a difference of a distance between the tilting links 221 and 222 can change according to a desired angle to be tilted. A tilting plate 117c, on which a slide limitation guide path 112c and a rotation limiting part 115c are formed, is installed at each upper end of the tilting links 221 and 222. Although the rotation limiting part 115 is formed along a route in a circular arc-shape having a uniform radius of curvature in the above described embodiments, the rotation limiting part 115c in the present invention may have an elliptic arc-shape or a shape formed by another curved line. Furthermore, the rotation limiting part 115c can be formed in a linear shape. This will be described in more detail when the link device 170c will be described below. According to the rotational angle of the tilting links 221 and 222, the tilting plate 117c can be installed in such a manner that it is bent at predetermined angle to be lifted respective to the first body 110c or in such a manner that it is horizontally folded in parallel with the first body 110c. A hole 111c for installation of the rotation axis member 120 is formed at the tilting plate 117c. The rotation axis member 120 is installed through the hole 111c in such a manner that it can rotate from a fixed position, and a plate member 119c is installed at a lower surface of the tilting plate 117c so as to support the rotation axis member 120.

The guide member 140c is assembled with the rotation axis member 120 and is installed at the tilting plate 117c in such a manner that the guide member 140c can rotate from a fixed position. A pair of slide guide parts 141c is installed at each edge of both sides of the guide member 140c so as to allow the second body 150c having a large width to stably slide. As the case may be, it could be understood that the slide guide path can be formed in a shape similarly to that of the embodiment described above.

A first auxiliary member 152c and a second auxiliary member 155c, which are assembled with a bottom surface of the second body 150c, are installed at an upper side of the guide member 140c. A pair of guided slide parts 151c, which is assembled with the slide guide parts 141c, is formed at left and right sides of the first auxiliary member 152c. This second auxiliary member 155c is assembled with a bottom surface of the first auxiliary member 152c, and has a U-shape where a transverse center is perforated. The second auxiliary member 155c provides space for installation of the link device 170c and a slide torsion spring 180. The guided slide parts 151c may be directly formed at the second body 150c.

The slide torsion spring 180 is installed between the guide member 140c and the second auxiliary member 155c assembled with the second body 150c.

Differently from the embodiments described above, the link device 170c in this embodiment includes three link members. In more detail, the link device 170c includes a first link member 171c rotatably installed at the guide member 140c, a second link member 175c, which has one end rotatably connected with the first link member 171c and the other end rotatably supported by the second body 150c, and a third link member 177c, which is rotatably installed at one side of the first link member 171c and has one side connected with the interlocking member 130c. As a result, there is no need to form the rotation limiting part 115c, which is assembled with the interlocking member 130 so as to limit rotation of the second body 150c when the second body 150c slides, along a circular arc having a center corresponding to a rotational center of the first link member 171c. Therefore, the rotation limiting part 115c can have a shape formed by a curved line, such as an elliptic shape. As the case may be, in the present embodiment, the rotation limiting part 115c may be formed in a linear shape.

Also, in this embodiment, in a state of the second body 150c being closed, the interlocking member 130 is located at a part of the rotation limiting part 115c, which is positioned at a side spaced from the slide limitation guide path 112c. Therefore, the second body 150c can not rotate in a closed state. The second body 150c is opened through sliding as shown in FIG. 21, and the interlocking member 130 is moved toward the slide limitation guide path 112c due to the operation of the link device 170c so as to escape from the rotation limiting part 115c. Accordingly, as shown in FIG. 22, the second body 150c can rotate in a state of it being opened through sliding.

An interlocking member guide path 142c formed at the guide member 140c is formed in a shape equal to the shape of the rotation limiting part 115c. The rotation limiting part 115c is connected with one end of the slide limitation guide path 112c so that the rotation limiting part 115c is arranged in such a manner that it overlaps the interlocking member guide path 142c when the second body 150c slides or when the second body 150c is closed.

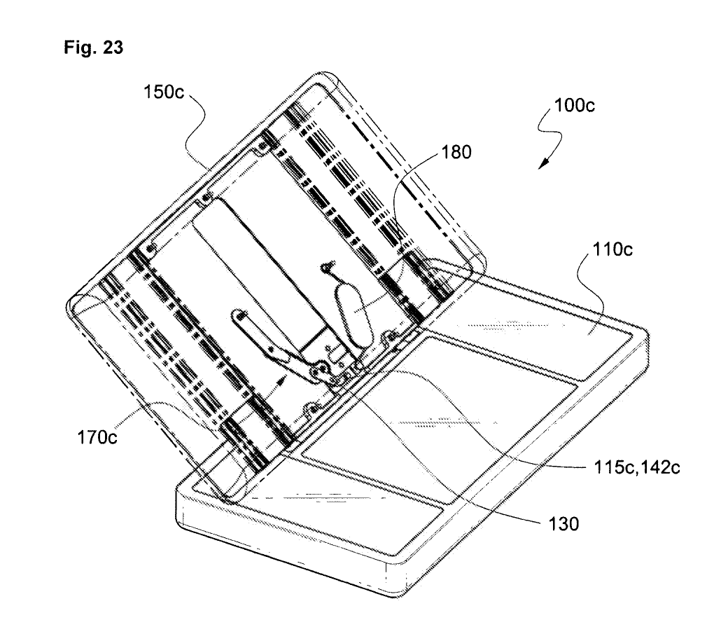

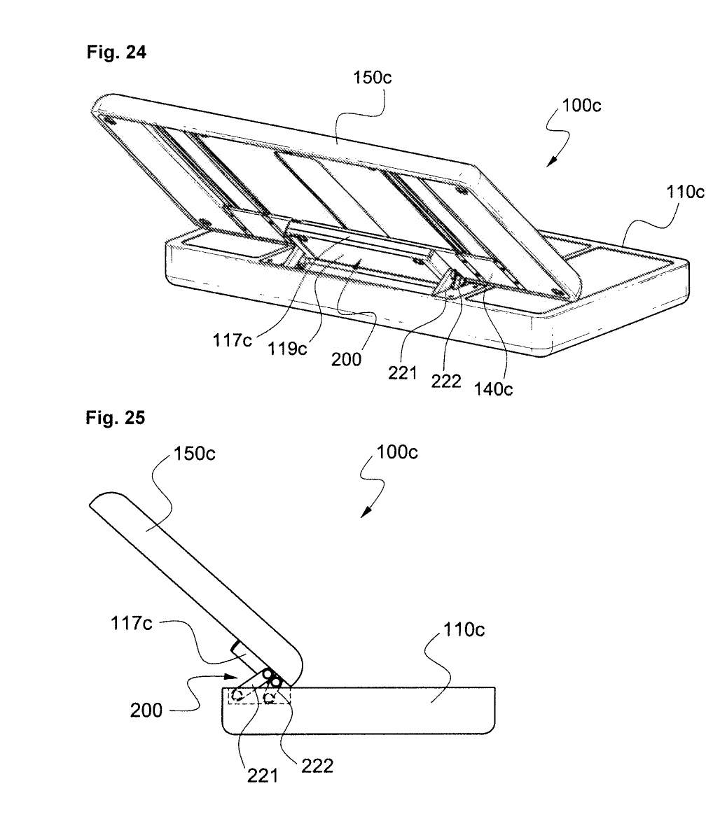

FIG. 23 is a perspective view of the portable electronic device, in which the second body is tilted in the state of FIG. 21, FIG. 24 is a perspective view of the portable electronic device, in which a rear surface of the device is shown, and FIG. 25 is a side view of the portable electronic device of FIG. 23.

As shown in FIG. 21, in a state where the second body 150c is opened through sliding, if the second body 150c is lifted up a little, the tilting links 221 and 222, which are transversely arranged, stand so as to lift up the tilting plate 117c a little. At this time, the tilting links 221 and 222 lift up a rear side of the tilting plate 117c to a higher degree so that the tilting plate 117c can be tilted at a predetermined tilting angle. The tilting angle is below 90 degrees, and is preferably 30 or 45 degrees. Herein, as shown in FIG. 24, the tilting links 221 and 222 have to be arranged at positions which miss each other in left and right sides, respectively. This is because such an arrangement can prevent the tilting links 221 and 222 from interfering with each other when they tilt the tilting plate 117c or allows it to lie in parallel with the second body 150c.

The portable electronic device according to the present invention, which is shown in FIG. 18 to 25, may be usefully applied to a product having a width larger than a length, such as a PDA, a potable game player, etc.

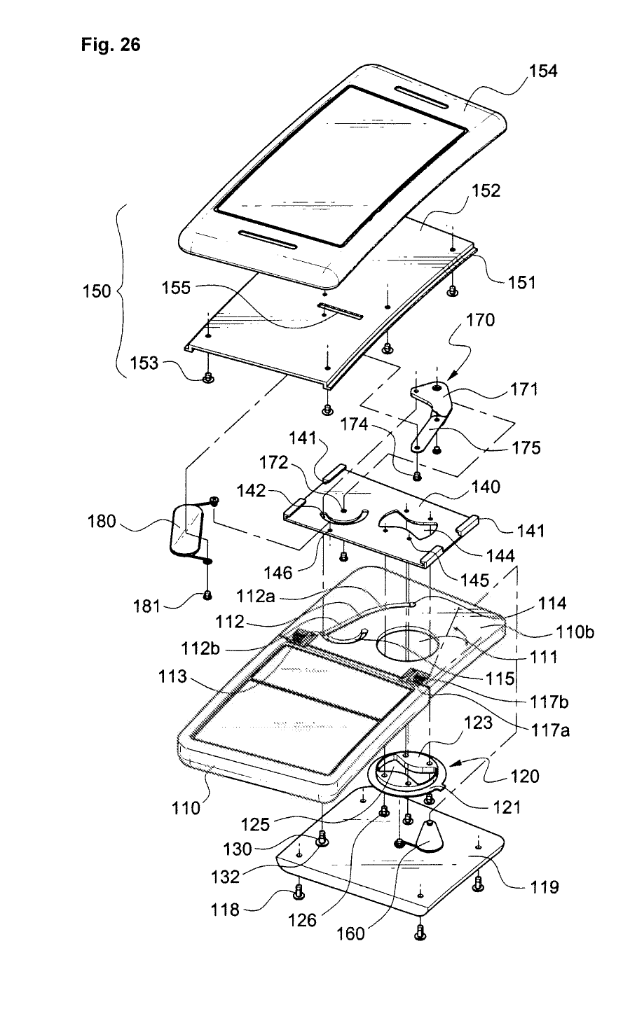

FIG. 26 is an exploded perspective view of a modified example of the portable electronic device of FIG. 2.

As shown, a tilting part 110b is installed at an upper end of the first body 110 through hinges 117a, and the guide member 140 is installed at the tilting part 110b. Therefore, after the second body 150 is opened through sliding or is opened through rotation, it is possible for the second body 150 to be lifted up and bent at a predetermined angle so as to be tilted, or to be again positioned in parallel with the first body 110 in a state of the second body 150 being tilted. A torsion spring 117b is installed at a shaft of each hinge 117a so as to allow the second body 150 to automatically tilt while sliding or rotating to be opened. The remaining structure of the device is equal to the structure described in FIG. 2.

In addition to the structure allowing the opened second body to be tilted, which is described in FIGS. 18 to 26, it is possible to configure another structure.

The sliding/rotation opening/closing portable electronic device, the sliding/rotation opening/closing module for the device, and a part thereof according to the present invention can be used in implementing a cover of the portable electronic device, which can be opened through sliding and rotation.

Particularly, it is possible to use the present invention in adjusting the transverse center of the cover to the center of a main body when the cover is opened through rotation.

Also, the present invention can be used to increase the width of a sliding/rotation opening/closing portable terminal and increase the area of a main body, at which keys, etc. can be installed.

In addition, the present invention can be used to allow the second body to be tilted in an opened state.

According to the present invention, a second body is restrictively slid respective to a guide member rotatably installed at a first body while the second body rotates through the guide member so that it possible to adjust a position of the second body, which has been opened through rotation, leftward or rightward, or to adjust the transverse center of the second body with respect to the first body.

Accordingly, a position of a rotational center of the guide member can be moved from the edge of a first body to an inner side thereof and from a lower side of the first body to an upper side thereof, and a large width of the portable electronic device can be secured.

In addition, a position of a rotation axis member can be adjusted so that the portable electronic device can be freely designed, and the first and second bodies can be supported by at least two spots so that an assembling structure is stable, and the portable electronic device isn't easily damaged.

When the position of the rotational axis member supporting a guide member in such a manner that the guide member can be rotated on the first body is moved upward, it is possible to increase the sliding distance of the second body, and the area of the first body, which has input keys, etc. installed thereon, and is exposed when the second body is rotated to be opened, can be enlarged.

According to need, the opened second body can be tilted so that it is convenient for the user to use the electronic device.

What is claimed is:

1. A sliding/rotation opening/closing portable electronic device comprising:
a first body;
a guide member, which is installed at the first body in such a manner that the guide member can rotate about a rotation axis member, and has a slide guide part;
an interlocking member installed at between the first body and the guide member, the interlocking member interlocking relative movements of the first body lo and the guide member through a section where a relative position of the interlocking member respective to the first body and the guide member changes according to each operation of the first body and the guide member when the guide member rotates;
a second body slidably installed at the slide guide part;
a link device, which is installed between the guide member and the second body and has one side connected with the interlocking member, the link device being folded or unfolded while the link device is rotated by the interlocking member so as to allow the second body to slide when the guide member rotates, so that a relative position of the second body respective to the guide member changes.

2. The sliding/rotation opening/closing portable electronic device as claimed in claim 1, wherein a slide limitation guide path is formed at the first body along a periphery of the rotation axis member and has a section where distance from the slide limitation guide path to a rotational center of the rotation axis member is changes, so that the slide limitation guide path restrictively allows the second body to slide along the guide member in such a manner that the slide limitation guide path allows the interlocking member to be restrictively moved while allowing the guide member to rotate when the guide member performs a rotational movement, and
an interlocking member guide path is formed at the guide member along a route having at least one portion intersected with the slide limitation guide path when the guide member rotates, and allows a position of the interlocking member respective to the first body and the guide member to be changed in a state where the interlocking member is interlocked.

3. The sliding/rotation opening/closing portable electronic device as claimed in claim 2, wherein the rotation axis member is installed at the first body in such a manner that it is deviated toward a right side or a left side of an upper end of the first body, and a degree of change in a distance between the slide limitation guide path and the rotational center of the rotation axis member in the section has been determined so as to allow the second body to slide along the slide guide part while rotating about the rotation axis member, thereby adjusting a transverse center of the second body with respect to the first body, when the second body is opened through rotation.

4. The sliding/rotation opening/closing portable electronic device as claimed in claim 2, wherein the first body has a rotation limiting part formed along a route, which prevents or restrictively allows rotation of the second body while allowing the second body to slide in performing a sliding operation.

5. The sliding/rotation opening/closing portable electronic device as claimed in claim 4, wherein the link device includes a first link member rotatably installed at the guide member, and a second link member which is rotatably connected with the first link member and is rotatably supported by the second body,
the interlocking member is connected with one side of the first link member, and
the rotation limiting part is connected with one end of the slide limitation guide path, the rotation limiting part having a circular arc-shape having a center corresponding to a rotational center of the link device, and being formed in such a manner that the rotation limiting part overlaps the interlocking member guide path when the second body slides or is closed.

6. The sliding/rotation opening/closing portable electronic device as claimed in claim 4, wherein the link device includes a first link member rotatably installed at the guide member, a second link member, which is rotatably connected with the first link member and is rotatably supported by the second body, and a third link member, which is rotatably installed at one side of the first link member and has one side connected with the interlocking member, and
the rotation limiting part is connected with one end of the slide limitation guide path, the rotation limiting part being shaped by a curved line or a linear line and being formed in such a manner that the rotation limiting part overlaps the interlocking member guide path when the second body slides or is closed.

7. The sliding/rotation opening/closing portable electronic device as claimed in claim 1, wherein a rotation torsion spring for providing torsion force to the rotation axis member is installed between the rotational axis member and the first body, and a sliding torsion spring for providing elastic force in a direction where the second body slides is installed between the second body and the guide member.

8. The sliding/rotation opening/closing portable electronic device as claimed in claim 1, wherein a hole is formed at the first body, the rotation axis member includes a supporting part, which is locked in an edge of the hole so as to be rotatably supported by the first body, and a guide member assembling part protruding toward a side opposite to the supporting part through the hole so as to be assembled with the guide member, and a through hole for allowing an FPC connector to pass through the through hole is formed at the rotation axis member and the guide member.

9. The sliding/rotation opening/closing portable electronic device as claimed in claim 1, wherein the first body and the second body have a linear shape or a curved shape.

10. A sliding/rotation opening/closing module comprising:
a first body connection part;
a guide member, which is rotatably installed at the first body connection part through a rotation axis member and has a slide guide part;
an interlocking member, which is installed between the first body connection part and the guide member, and interlocks relative movements between the first body connection part and the guide member in a section where a position of the interlocking member respective to the first body connection part and the guide member changes according to each operation of the first body connection part and the guide member when the guide member rotates; and
a link device, which is installed between the guide member and the second body or between the guide member and the second body connection part, and has one side connected with the interlocking member, the link device being folded or unfolded while the link device is rotated by the interlocking member when the guide member rotates so as to allow the second body or the second body connection part to slide, so that a position of the second body or the second body connection part respective to the guide member changes,
wherein the sliding/rotation opening/closing module is installed in a portable electronic device in such a manner that it is positioned between a first body and a second body or the second body connection part so as to allow the second body to be opened/closed by a sliding and rotating operation respective to the first body.

11. The sliding/rotation opening/closing module as claimed in claim 10, wherein a slide limitation guide path is arranged on the first body connection part along a periphery of the rotation axis member and has a section where distance from the slide limitation guide path to a rotational center of the rotation axis member changes so that the slide limitation guide path restrictively allows the second body connection part to slide along the guide member in such a manner that the slide limitation guide path restrictively moves the interlocking member while allowing the guide member to rotate when the guide member performs a rotational movement, and
an interlocking member guide path is formed at the guide member along a route having at least one portion intersected with the slide limitation guide path when the guide member rotates, and allows a position of the interlocking member respective to the first body connection part and the guide member to change in a state where the interlocking member is interlocked.

12. The sliding/rotation opening/closing module as claimed in claim 11, wherein the rotation axis member is installed at the first body connection part in such a manner that it is deviated toward a right side or a left side of an upper end of the first body connection part, and a degree of a change in a distance between the slide limitation guide path and the rotational center of the rotation axis member in the section has been determined so as to allow the second body or the second body connection part to slide along the slide guide part while rotating about the rotation axis member, thereby adjusting a transverse center of the second body or the second body connection part with respect to the first body connected with the first body connection part, when the second body or the second body connection part is opened through rotation.

13. The sliding/rotation opening/closing module as claimed in claim 11, wherein the first body connection part has a rotation limiting part formed along a route, which prevents or restrictively allows rotation of the second body or the second body connection part while allowing the second body or the second body connection part to slide in performing a sliding operation.

14. The sliding/rotation opening/closing module as claimed in claim 13, wherein the link device includes a first link member rotatably installed at the guide member and a second link member, which is rotatably connected with the first link member and will be rotatably supported by the second body,
the interlocking member is connected with one side of the first link member, and
the rotation limiting part is connected with one end of the slide limitation guide path, the rotation limiting part having a circular arc-shape having a center corresponding to a rotational center of the link device, and being formed in such a manner that the rotation limiting part overlaps the interlocking member guide path when the second body or the second body connection part slides or is closed.

15. The sliding/rotation opening/dosing module as claimed in claim 13, wherein the link device includes a first link member rotatably installed at the guide member, a second link member, which is rotatably connected with the first link member and will be rotatably supported by the second body, and a third link member, which is rotatably installed at one side of the first link member and has one side connected with the interlocking member, and
the rotation limiting part is connected with one end of the slide limitation guide path, shaped by a curved line or a linear line, and formed in such a manner that the rotation limiting part overlaps the interlocking member guide path when the second body slides or is closed.

16. The sliding/rotation opening/closing module as claimed in claim 10, wherein a rotation torsion spring for providing torsion force to the rotation axis member is installed between the rotational axis member and the first body connection part, and a sliding torsion spring for providing elastic force in a direction where the second body or the second body connection part slides is installed between the second body and the guide member or between the second body connection part and the guide member.

17. The sliding/rotation opening/closing module as claimed in claim 10, wherein a hole is formed at the first body connection part, the rotation axis member includes a supporting part, which is locked in an edge of the hole so as to be rotatably supported by the first body connection part, and a guide member assembling part protruding toward a side opposite to the supporting part through the hole so as to be assembled with the guide member, and a through hole for allowing a FPC connector to pass through the through hole is formed at the rotation axis member and the guide member.

18. The sliding/rotation opening/closing module as claimed in claim 10, wherein the first body connection part and the second body or the second body connection part have a linear shape or a shape curved in a transverse direction.

19. A first body for a sliding/rotation opening/closing portable electronic device, the first body comprising:
a slide limitation guide path, which is formed along a periphery of a rotation axis member installation part and has a section where distance from the slide is limitation guide path to a rotational center of the rotation axis member changes so as to allow an interlocking member interlocked with the slide limitation guide path to be restrictively moved while allowing rotation of a guide member when the guide member rotatably installed through the rotation axis member rotates, so that the slide limitation guide path restrictively allows a second body slidably installed at the guide member to slide along the guide member, and
a rotation limiting part formed along a route, which prevents or restrictively allows rotation of the second body while allowing the second body to slide when the second body performs a sliding operation.

20. A first body connection part for a sliding/rotation opening/closing module, the first body connection part comprising:
a slide limitation guide path, which is formed along a periphery of a rotation axis member installation part and has a section where distance from the slide limitation guide path to a rotational center of the rotation axis member changes so as to allow an interlocking member interlocked with the slide limitation guide path to be restrictively moved while allowing rotation of a guide member when the guide member rotatably installed through the rotation axis member rotates, so that the slide limitation guide path restrictively allows a second body connection part slidably installed at the guide member to slide along the guide member; and
a rotation limiting part formed along a route, which prevents or restrictively allows rotation of the second body connection part while allowing the second body connection part to slide when the second body connection part performs a sliding operation.

21. The sliding/rotation opening/closing portable electronic device as claimed in claim 1, wherein a pair of slide guide parts is installed at left and right sides of the guide member respectively, and a pair of guided slide parts, which is assembled with the slide guide parts to be guided, is installed at left and right sides of the second body respectively.

22. The sliding/rotation opening/closing portable electronic device as claimed in claim 1, wherein the guide member is installed in such a manner that the guide member can be tilted by a tilting part installed at the first body.

23. The sliding/rotation opening/closing portable electronic device as claimed in claim 1, wherein the upper part of the first body is installed at the lower part of the first body through a hinge so that the first body has a tilting part, which can be bent in an upper direction, and the guide member is installed at the tilting part.

24. The sliding/rotation opening/closing module as claimed in claim 10, wherein a pair of slide guide parts is installed at left and right sides of the guide member respectively, and a pair of guided slide parts, which is assembled with the slide guide parts to be guided, is installed at left and right sides of the second body or the second body connection part respectively.

25. A portable electronic device comprising:
a first body;
a tilting part, which is tiltably installed at an upper end of the first body, and can be raised in such a manner that it is bent in an upper direction and can be again unfolded in a state where the tilting part has been bent to be raised;
a guide member, which is installed at the tilting part and has a slide guide part; and
a second body slidably installed at the slide guide part,
wherein the second body can be bent at an acute angle respective to the first body in a state where the second body is opened through sliding.

26. The portable electronic device as claimed in claim 25, wherein the guide member is installed at the tilting part in such a manner that the guide member can rotate about a rotation axis member, and the second body can be bent at an acute angle respective to the first body in a state where the second body is opened through rotation.

27. A portable electronic device comprising:
a first body;
a tilting part, which is tiltably installed at an upper end of the first body, and can be raised in such a manner that it is bent in an upper direction and can be again unfolded in a state where the tilting part has been bent to be raised; and
a second body rotatably installed at the tilting part,
wherein the second body can be bent at an acute angle respective to the first body in a state where the second body is opened through rotation.
